(19) United States
(12) Patent Application Publication
(10) Pub. No.: US 2025/0372167 A1
(43) Pub. Date: Dec. 4, 2025

(54) MEMORY DEVICE INCLUDING PILLAR SUPPORT STRUCTURES

(71) Applicant: Micron Technology, Inc., Boise, ID (US)

(72) Inventors: Justin David Shepherdson, Meridian, ID (US); Sidhartha Gupta, Boise, ID (US); Anna Maria Conti, Milano (IT)

(21) Appl. No.: 19/224,003

(22) Filed: May 30, 2025

Related U.S. Application Data
(60) Provisional application No. 63/654,702, filed on May 31, 2024.

(51) Int. Cl. G11C 16/04; G11C 5/06; H01L 21/768; H10B 41/10; H10B 41/27; H10B 43/10; H10B 43/27

(52) U.S. Cl. CPC G11C 16/0483; G11C 5/063; H01L 21/76843; H10B 41/10; H10B 41/27; H10B 43/10; H10B 43/27

(57) ABSTRACT

Some embodiments include apparatuses and methods of forming the apparatuses. One of the apparatuses includes a memory device, which includes: a first deck including first levels of conductive materials interleaved with first levels of dielectric materials; a second deck including second levels of conductive materials interleaved with second levels of dielectric materials; memory cell strings including pillars extending through at least a portion of each of the first deck and the second deck; a first conductive contact contacting a level of the first levels of conductive materials; a second conductive contact contacting a level of the second levels of conductive materials; and a dielectric pillar extending in the direction from the first deck to the second deck, the dielectric pillar including an end portion between the level of the first levels of conductive material and the level of the second levels of conductive materials.

### PRIORITY APPLICATION

This application claims the benefit of priority to U.S. Provisional Application Ser. No. 63/654,702, filed May 31, 2024, which is incorporated herein by reference in its entirety.

### BACKGROUND

Dimensions of structures of some of the components in a memory device (e.g., a flash memory device) are relatively small (e.g., in nanometer size). At a certain small dimension of a memory device, structural damage (e.g., collapse) in part of the memory device may occur during fabrication. Such collapse can negatively affect yield, cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3 shows a detailed schematic diagram of two blocks of the memory device of FIG. 2, according to some embodiments described herein.

FIG. 4 shows a top view of a structure of a portion of the memory device of FIG. 3 including a region of a memory array, a conductive contact region, and structures between the blocks of the memory device, according to some embodiments described herein.

FIG. 5 shows a side view (e.g., cross-section) of a structure of a portion of the memory device of FIG. 4, including tiers of materials that include respective memory cells and control gates associated with the memory cells, according to some embodiments described herein.

FIG. 6 shows a top view of the structure of the memory device of FIG. 4, including dielectric pillars (e.g., support structures), according to some embodiments described herein.

FIG. 7 shows a side view (e.g., cross-section) of a portion of the memory device of FIG. 6, including decks and the dielectric pillars, according to some embodiments described herein.

FIG. 8A and FIG. 8B show different side views (e.g., cross-sections) of the memory device of FIG. 6, according to some embodiments described herein.

FIG. 9 shows a memory device that can be a variation of the memory device shown in FIG. 6, according to some embodiments described herein.

FIG. 10 shows a memory device that can be another variation of the memory device shown in FIG. 6, according to some embodiments described herein.

FIG. 11 shows a memory device that can be a variation of the memory device shown in FIG. 7, according to some embodiments described herein.

FIG. 12A through FIG. 17B show different views of elements during processes of forming a memory device including forming dielectric structures (e.g., support structures) of the memory device, according to some embodiments described herein.

### DETAILED DESCRIPTION

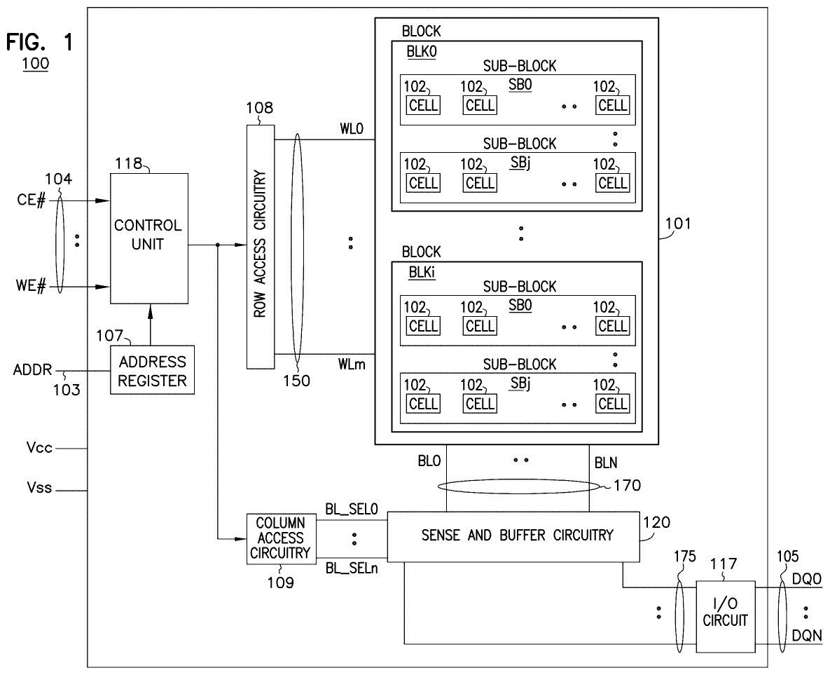

The techniques described herein involve a memory device including memory cells formed in tiers (different physical levels) of the memory device. The tiers include respective levels of conductive materials. The conductive materials form part of control gates (e.g., word lines) associated with the memory cells. The memory device also includes dielectric pillars (e.g., support structures) to provide structural support for part of the memory device. In an example, the support structures are formed to prevent damage (e.g., collapse or bending or both) in part of the tiers. As described in more detail below, the dielectric pillars have different dimensions (e.g., pillar heights and widths) depending on their locations in the memory device. The techniques described herein improve at least one of yield, cost, performance, and reliability associated with the memory device. Other improvements and benefits of the techniques described herein are further discussed below with reference to FIG. 1 through FIG. 17B.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks (memory cell blocks) BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SELO through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of the memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of the memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

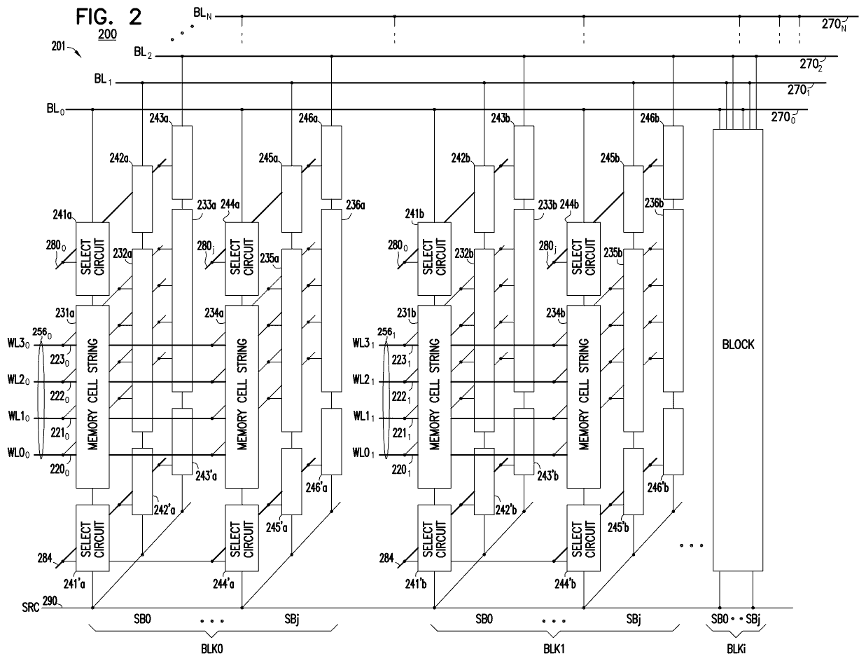

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 17B.

FIG. 2 shows a general schematic diagram of a portion of a memory device 200 including a memory array 201 having blocks (memory cell blocks or blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

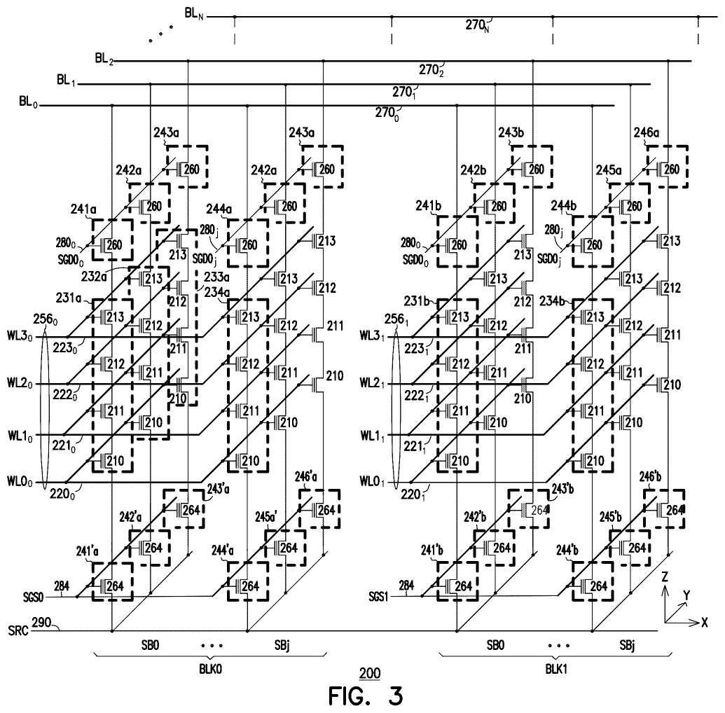

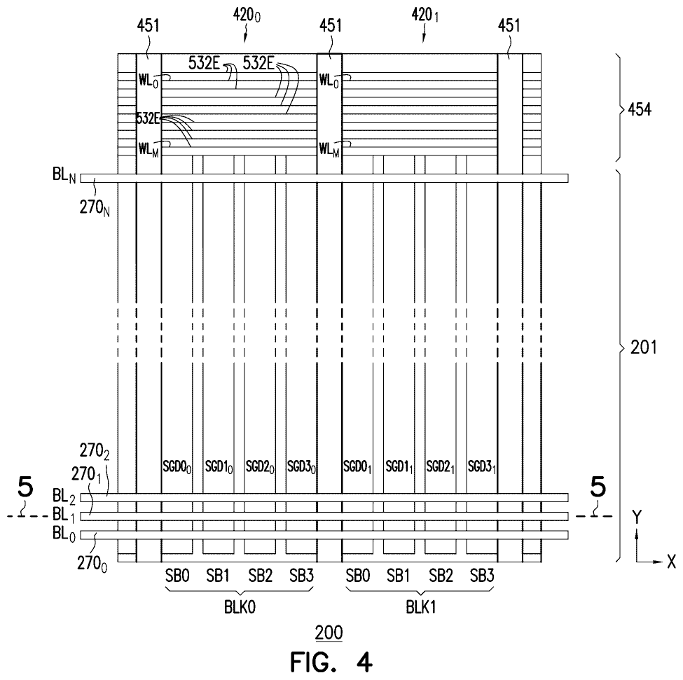

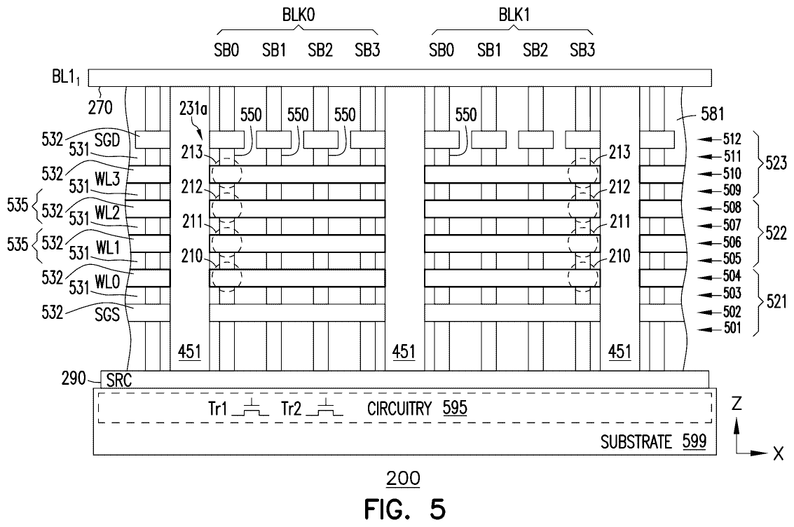

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3 and FIG. 4) and a pillar (e.g., pillar 550 in FIG. 5) where the series-connected memory cells can be located (e.g., vertically located) along respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 2701. Memory cell strings 233a, 236a (of block BLK0), 233b and 236b (of block BLK1) can share data line 2702.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL00, WL1₀, WL2₀, and WL3₀. Memory device 200 can use signals WL00, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK0 during an operation (e.g., read, write, or erase operation).

As shown in FIG. 2, in sub-block SB0 of block BLK0, memory device 200 can include a select line (e.g., drain select line) 2800 that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 2800, which is electrically separated from select line 2800 of block BLK1. Select line 2800 of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 2800 and 280ⱼ of block BLK1 are electrically separated from select lines 2800 and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 2800) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3) coupled between source 290 and a respective memory cell string. The source select gate (e.g., transistor) can be controlled (e.g., turned on or turned off) by a signal on a respective source select line based on a voltage provided to the signal.

FIG. 3 shows a detailed schematic diagram including blocks of the blocks BLK0 and BLK1 of memory device 200 of FIG. 2, according to some embodiments described herein. In FIG. 3, directions X, Y, and Z in FIG. 3 can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3. As shown in FIG. 3, each select line can carry an associated separate select signal. For example, in sub-block SB0 of block BLK0, select line (e.g., drain select line) 2800 can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 2800 can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3, similar drain select lines (and their associated signals) are given the same labels for simplicity. However, as shown in FIG. 3, the drain select lines (from the same block or from different blocks) of memory device 200 are electrically separated from each other and carry different signals (although the signals are given the same labels).

As shown in FIG. 3, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3, each of the memory cell strings (e.g., memory cell string 231a) of memory device 200 can include series-connected memory cells that include one of memory cells 210, one of memory cells 211, one of memory cells 212, and one of memory cells 213. FIG. 3 shows an example of four memory cells 210, 211, 212, and 213 in each memory cell string. The number of memory cells in each memory cell string can vary. For example, each memory string can include up to hundreds (or more) of memory cells.

As shown in FIG. 3, each drain select circuit (e.g., select circuit 241a) can include one of select gates 260. Each source select circuit (e.g., select circuit 241′a) can include one of select gates 264.

Each select gate 260 in FIG. 3 can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 2800 of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 2800 of sub-block SB0 of block BLK0) and can operate like a switch (e.g., a transistor).

In the physical structure of memory device 200, a select line (e.g., select line 2800 of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 2800 of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

FIG. 3 shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 4 shows a top view of a structure of a portion of memory device 200 of FIG. 2 and FIG. 3 including a region of memory array 201 and a region 454 of blocks BLK0 and BLK1, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3 are also not repeated.

In FIG. 4, structures 451 can be formed to separate (physically separate) one block and another block of memory device 200. Two adjacent blocks (e.g., blocks BLK0 and BLK1) can be separated from each other by one of the structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1. Structure 451 can be called a dielectric structure or a slit structure. The regions of memory device 200 at which structures 451 are located can be called slit regions.

In FIG. 4, the control gates associated with signals WL0 through WL_{M} in block BLK0 represent the control gates associated with signals WL0₀, WL1₀, WL2₀, and WL3₀ in FIG. 3. In FIG. 4, the control gates associated with signals WL₀ through WL_{M} in block BLK0 represent the control gates associated with signals WL0₁, WL1₁, WL2₁, and WL3₁ in FIG. 3. As shown in FIG. 4, structure 451 between block BLK0 and BLK1 separates (physically and electrically separate) the control gates associated with signals WL₀ through WL_{M} in block BLK0 from control gates associated with signals WL₀ through WL_{M} in block BLK1.

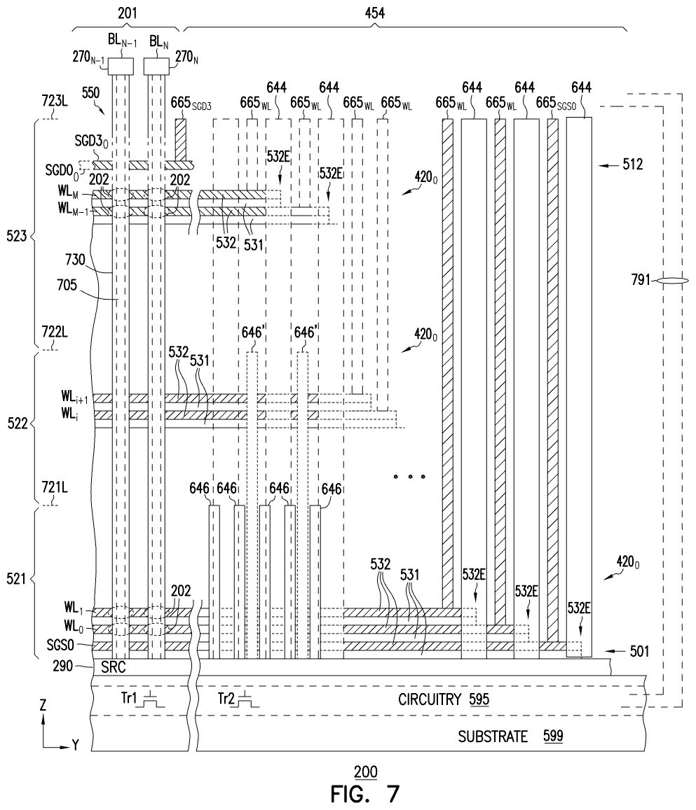

In FIG. 4, region 454 can be called staircase region. In region (e.g., staircase) 454, memory device 200 can include staircase structure 420₀ of block BLK0 and staircase structure 420₁ of block BLK1. In region 454, respective portions (e.g., end portions) of the conductive materials (e.g., conductive materials 532 shown in FIG. 5 and FIG. 7) and their respective edges (e.g., steps) 532E (also shown in FIG. 7) can collectively form staircase structures 420₀ and 420₁.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have structure like block BLK0. As shown in FIG. 4, block BLK1 can include control gates associated with signals WL₀ through WL_{M} (which represent the control gates associated with signals WL0₁, WL1₁, WL2₁, and WL3₁ in FIG. 3), select line (e.g., source select line) associated with signal SGS1 (also shown in FIG. 3), sub-blocks SB0, SB1, SB2, and SB3, select lines (e.g., drain select lines) SGD0₁, SGD1₁, SGD2₁, and SGD3₁.

A side view side view (e.g., cross-section) at memory array (memory cell array) 201 of memory device 200 along line 5-5 in FIG. 4 is shown in FIG. 5.

FIG. 5 shows a side view (e.g., cross-section) of a structure of a portion of memory device 200 of FIG. 4 including tiers (tiers of materials) 535 that include respective memory cells and control gates associated with (e.g., to control) the memory cells, according to some embodiments described herein. FIG. 5 also partially shows other blocks (on the left and right sides of blocks BLK0 and BLK1) of memory device 200.

As shown in FIG. 5, memory device 200 can include a substrate 599 and different levels 501 through 512 of memory device 200 over substrate 599 in the Z-direction. Levels 501 through 512 are physical device levels of memory device 200 over substrate 599. Memory device 200 can include decks 521, 522, and 523. Each of decks 521, 522, and 523 can include part of memory devices 200 in different physical levels (e.g., levels 501 through 512) of memory device 200.

Memory device 200 can include a dielectric material 581 formed over at least a portion of memory device 200. In FIG. 5, memory cells 210 Memory cells 210, 211, 212, and 213 of the memory cell strings (e.g., memory cell string 231a in FIG. 3) of respective sub-blocks SB0, SB1, SB3, and SB3 of each of blocks BLK0 and BLK1 can be formed over substrate 599 and source 290 (e.g., formed vertically in Z-direction in respective levels among levels 501 through 512).

As shown in FIG. 5, data line 2701 (associated with signal BL1) can extend in the X-direction across the blocks (e.g., blocks BLK0 and BLK1 and other blocks) of memory device 200. Data line 2701 can be shared by respective memory cell strings (including memory cell string 231a) of the blocks.

In FIG. 5, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 4. In another example, in block BLK1, the select line indicated by signal SGS can correspond to the select line (e.g., source select line) associated with signals SGS1 of block BLK1 shown in FIG. 4.

In FIG. 5, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 4. In another example, in block BLK1 in FIG. 5, the control gates indicated by signals WL0, WL1, WL2, and WL3 can correspond to respective control gates associated with signals WL0₁, WL1₁, WL2₁, and WL3₁, respectively, of block BLK1 shown in FIG. 4. FIG. 5 shows memory device 200 includes four control gates (associated with signals WL0, WL1, WL2, and WL3) as an example. However, memory device 200 can include numerous control gates (e.g., control gates associated with signals WL₀ through WL_{M}) as shown in FIG. 7.

As shown in FIG. 5, memory device 200 can include dielectric materials (e.g., silicon dioxide) 531 located on levels 503, 505, 507, 509, and 511. Dielectric materials 531 in a respective block are interleaved with conductive materials 532. Conductive materials 532 can form respective control gates (associated with signals WL0, WL1, WL2, and WL3) in the respective block. As shown in FIG. 5, dielectric materials 531 can be located on respective levels among levels 501 through 512. Conductive materials 532 can be located on respective levels (e.g., levels 502, 504, 506, 508, 510, and 512) among levels 501 through 512 that are interleaved with the levels of dielectric materials 531. Examples of conductive materials 532 (which form the control gates) include a single conductive material (e.g., single metal, e.g., tungsten) or a combination of different layers of conductive materials. For example, each of the control gates of blocks BLK0 and BLK1 can include (e.g., multi-layers of) aluminum oxide, titanium nitride, tungsten.

The levels of dielectric material 531 and the levels of conductive materials 532 can form tiers 535 of memory device 200. Each tier 535 can include a level of dielectric material 531 and a level of conductive material 532. For simplicity, only some of tiers 535 are labeled in FIG. 5. As shown in FIG. 5, tiers 535 can be located one over another and can include respective levels of memory cells 210, 211, 212, and 213, and control gates associated with the memory cells. FIG. 5 shows a few tiers (e.g., four tiers 535) of memory device 200 as an example. However, memory device 200 can include up to hundreds of tiers (or more than hundreds of tiers).

As shown in FIG. 5, memory device 200 can include pillars (memory cell pillars) 550 in blocks BL0 and BLK1. Each of the pillars 550 can be part of a respective memory cell string (e.g., memory cell string 231a). Each of the pillars 550 can have length extending through at least a portion of each of decks 521, 522, and 523 in the Z-direction (e.g., extending vertically from substrate 599) between substrate 599 and data line 270. As shown in FIG. 5, the Z-direction is also a direction at which the length of pillar 550 extends from one tier to another tier, which is also a direction from levels of dielectric materials 531 to levels of conductive materials 532.

As shown in FIG. 5, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5, memory device 200 can include circuitry 595 located in (e.g., formed in) substrate 599. At least a portion of the circuitry can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5, source 290 can include a conductive material (or materials, e.g., different levels of different materials) and can extend in the X-direction. FIG. 5 shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

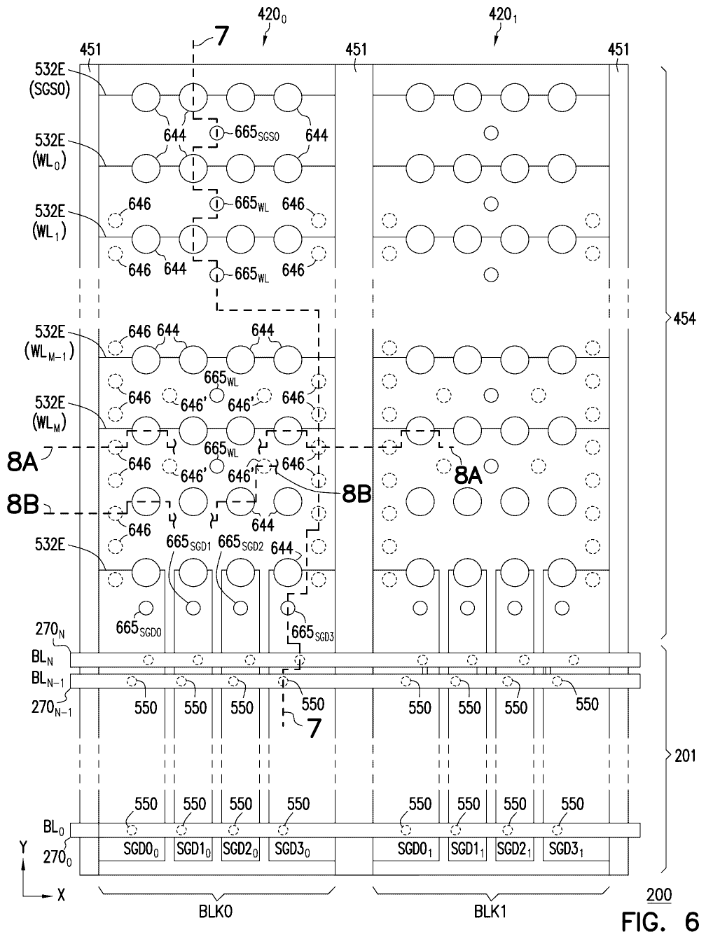

FIG. 6 shows a top view of a structure of memory device 200 of FIG. 4, according to some embodiments described herein. As shown in FIG. 6, pillars 550 (shown in top view) are located the region that is included in memory array 201, which is adjacent region 454. In region 454, memory device 200 can include conductive contacts (e.g., word line contacts) 665_{WL}, conductive contacts (e.g., drain select line contacts) 665_{SGD0}, 665_{SGD1}, 665_{SGD2}, and 665_{SGD3}, and conductive contact (e.g., source select line contact) 665_{SGS0}. Conductive contacts 665_{WL} can include metal (e.g., tungsten or other conductive materials).

Conductive contacts 665_{WL} can contact (form an electrical connection with) respective control gates of memory device 200. FIG. 6 shows top view of the control gates of memory device 200 associated with signals WL₀ through WL_{M}. Conductive contacts 665_{WL} can be part of respective access lines (e.g., word lines) of memory device 200. Conductive contacts 665_{WL} allow signals (e.g., signals WL₀ through WL_{M} that represent signals WL0₀, WL1₀, WL2₀, and WL3₀ in block BLK0 in FIG. 3) to be provided to respective control gates of block BLK0 through conductive contacts 665_{WL}. FIG. 7 (described in more detail below) show side views (e.g., cross-sections) of memory device 200 including of conductive contacts 665.

Similarly, for block BLK1 in FIG. 6, the conductive contacts (e.g., not labeled) can be formed at region 454 to allow signals (e.g., signals WL0₁, WL1₁, WL2₁, and WL3₁ in block BLK1 shown in FIG. 3) to be provided to respective control gates of block BLK1 through the conductive contacts at region 454.

In FIG. 6, the sub-blocks (associated with signals SGD0₀, SGD1₀, SGD2₀, and SGD3₀) of memory device 200 can include respective pillars 550 associated with a respective select line (one of the select lines associated with signals SGD0₀, SGD1₀, SGD2₀, and SGD3₀). Pillars 550 in the sub-blocks (associated with signals SGD0₀, SGD1₀, SGD2₀, and SGD3₀) are also associated with (e.g., coupled to) data lines 270₀ through 270_{N}.

As shown in FIG. 6, data lines 270₀ through 270_{N} can extend across (in the X-direction) the blocks (e.g., blocks BL0 and BL1) and located over and in electrical contact with pillars 550. Connections (e.g., vertical connections in the Z-direction) between pillars 550 and data lines 270₀ through 270_{N} are not shown in FIG. 6. However, each pillar 550 in the same sub-block of a block can be coupled to a separate (e.g., unique) data line among data lines 270₀ through 270_{N}.

FIG. 6 also shows top views of dielectric pillars 644, dielectric pillars 646, and dielectric pillars 646′. Dielectric pillars 646 can be formed in a row adjacent dielectric structure 451. Each of dielectric pillars 644, 646, and 646′ includes a dielectric structure having lengths (shown in FIG. 7) extending the Z-direction. Dielectric pillars 644, 646, and 646′ can include a dielectric material (or dielectric materials). Dielectric pillars 644, 646 and 646′ can have the same material (e.g., silicon dioxide). Alternatively, dielectric pillars 644, 646, and 646′ can have different materials. For example, the material of dielectric pillars 644 can be different from the material of one or both of dielectric pillars 646 and 646′. In another example, dielectric pillars 646 and 646′ can have the same material (e.g., silicon dioxide) and dielectric pillars 644 can have a material that is different from the material of dielectric pillars 646 and 646′.

Dielectric pillars 644, 646, and 646′ can be formed to provide structural support to a portion (e.g., region 454) of memory device 200 (e.g., support during part of the processes of forming memory device 200).

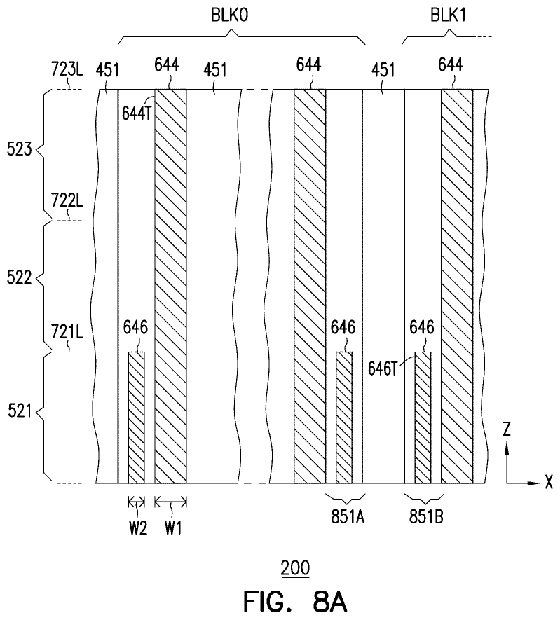

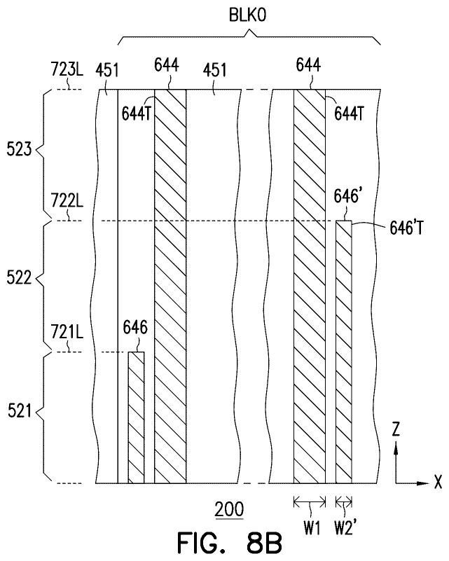

Different side views (e.g., cross-sections) of memory device 200 along lines 7-7, 8A-8A, and 8B-8B in FIG. 6 are shown in FIG. 7, FIG. 8A, and FIG. 8B, respectively.

FIG. 7 shows a side view in the Y-Z direction of a portion of memory device 200 including conductive contacts 665_{WL}, 665_{SGD3}, and 665_{SGS0} in region 454, dielectric pillars 644, 646, and 646′ in region 454, and pillar 550 in memory array 201, according to some embodiments described herein. FIG. 8A and FIG. 8B shows side views in the X-Z direction of a portion of memory device 200 along lines 8A-8A and 8B-8B, respectively, according to some embodiments described herein.

In FIG. 7, decks 521, 522, and 523 of memory device 200 are the same as those shown in FIG. 5.

FIG. 7 also shows levels 721L, 722L, and 723L of memory device 200 that can represent example boundaries (e.g., relative locations in the Z-directions) of decks 521, 522, and 523. For example, deck 521 can include a portion of memory device 200 between source 290 and level 721L. Deck 522 can include a portion of memory device 200 between level 721L and level 722L. Deck 523 can include a portion of memory device 200 between level 722L and level 723L. FIG. 7 shows memory device 200 including three decks (e.g., decks 521, 522, and 523) as an example. However, the number of decks in memory device 200 can be different from three.

As shown in FIG. 7, memory device 200 can include conductive paths (e.g., conductive routings) 791 to form circuit paths between circuitry 595 and other elements of memory device 200. This allows the control gates to couple to circuitry 595 through conductive lines conductive lines 656 (FIG. 6) and conductive paths 791 (FIG. 7).

As shown in FIG. 7, pillar 550 can be located in the portion of memory device 200 that includes memory array 201, which is also shown in top view in FIG. 6. Each pillar 550 can extend through conductive materials 532 (which form the control gates and the select lines) and dielectric materials 531 of tiers in the region included in in memory array 201.

As shown in FIG. 7, memory device 200 can include a structure 730 and a dielectric material 705 that can be part of pillar 550. Structure 730 and a dielectric material 705 can extend continuously (in the Z-direction) through decks 5221, 522, and 523 along the length of the respective pillar 550. Dielectric material 705 can include silicon dioxide. Structure 730 can be electrically coupled to source 290 and a respective data line (e.g., one of data line 270₀ through 270_{N} in FIG. 3 and FIG. 6). Structure 730 of a respective pillar 550 in a block is adjacent portions of respective control gates of that block. For example, structure 730 of pillar 550 in block BLK0 is adjacent to the control gates associated with signals WL₀ through WL_{M}, respectively, in block BLK0. In FIG. 7, memory cells 202 associated with a pillar 500 represent memory cells 210, 211, 212, and 213 of a memory cell string (e.g., memory cell string 231a in FIG. 3 and FIG. 5).

Structure 730 can include a conductive structure that can be part of a conductive path (e.g., pillar channel structure) to conduct current between a respective data line (e.g., one of data line 270₀ through 270_{N} in FIG. 3 and FIG. 6) coupled to structure 730 and source 290. Structure 730 can also include a material (or materials) that can form a charge storage element (e.g., a memory element) of a respective memory cell located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7, the control gates associated with signals WL₀ through WL_{M} and the select lines associated with signals (e.g., drain select signal and source select signal) SGD0₀ and SGS0 can be structured (e.g., patterned), such that they may have different lengths in the Y-direction. For example, the control gates (formed from respective materials 532) associated with signals WL₀ through WL_{M} can have different lengths measuring between pillar 550 and edges 532E (in the Y-direction) of respective the control gates. Edges 532E are part of respective conductive materials 532. As shown in FIG. 7, the control gates associated with signals WL₀ through WL_{M} can have different lengths, such that edges 532E can be form part of staircase structure 420₀.

As shown in FIG. 7, each of decks 521, 522, and 523 can include a portion (e.g., a subset) of control gates of memory device 200. For example, deck 521 can include the control gates associated with signals WL₀ and WL₁ (and other control gates, not shown). Deck 522 can include the control gates associated with signals WLᵢ and WLᵢ₊₁ (and other control gates, not shown) that are located over (in the Z-direction) the control gates of deck 521. Deck 523 can include the control gates associated with signals WL_{M-1} and WL_{M} (and other control gates, not shown) that are located over (in the Z-direction) the control gates of deck 522.

As shown in FIG. 7, conductive contacts 665_{WL} coupled to (e.g., contacting) the control gates (e.g., control gates associated with signals WL₀ and WL₁) of deck 521 can extend (in the Z-direction) through deck 522 and 523 and at least partially through deck 521.

Conductive contacts 665_{WL} coupled to (e.g., contacting) the control gates (e.g., control gates associated with signals WLᵢ and WLᵢ₊₁) of deck 522 can extend (in the Z-direction) through deck 523 and at least partially through deck 522 and may not extend below level 721L in the Z-direction.

Conductive contacts 665_{WL} coupled to (e.g., contacting) the control gates (e.g., control gates associated with signals WL_{M-1} and WL_{M}) of deck 523 can extend (in the Z-direction) from level 722L and may not extend below level 722L in the Z-direction (e.g., may not extend through deck 521 and 522).

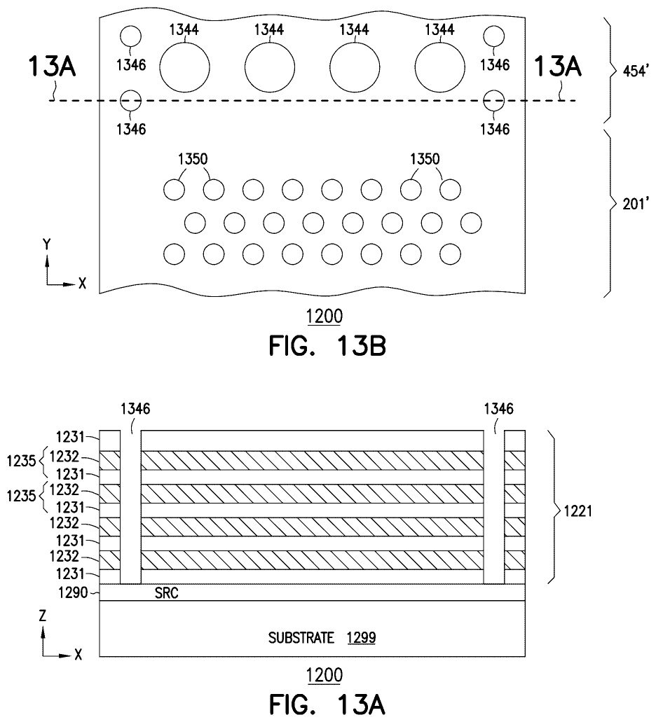

For example, during the processes of forming memory device 200 that can be similar to the processes of forming memory device 1200 of FIG. 12A through FIG. 17B, collapse or bending or both may occur in the tiers (e.g., tiers 535 in FIG. 5 and FIG. 7) at region 454 of memory device 200. Dielectric pillars 644, 646, and 646′ can be formed in memory device 200 to prevent such tier collapse or bending or both. In an alternative structure of memory device 200, dielectric pillars 646 or 646′ or both can be removed (not to be included in) from memory device 200. However, including dielectric pillars 646 or 646 or both in memory device 200 (as shown in FIG. 7) can further improve support for the structure (e.g., at region 454) of memory device 200. The support associated with dielectric pillars 646 and 646′ lead to improvement in at least one of yield, cost, performance, and reliability of memory device 200 and other memory devices (e.g., memory devices 900, 1000, 1100, and 1200 described herein.

The following description refer to FIG. 7, FIG. 8A, and FIG. 8B. For simplicity, FIG. 8A and FIG. 8B omit details of deck 521, 522, and 523. For example, the control gates associated with signals sWL₀ and WL_{M} (FIG. 7) and dielectric materials 531 and conductive materials 532 are not shown in FIG. 8A and FIG. 8B.

As shown in FIG. 7, FIG. 8A, and FIG. 8B, dielectric pillars 644, 646, and 646′ can include respective lengths extending in the Z-direction (e.g., extending through tiers 535). Dielectric pillars 644, 646, and 646′ can contact (e.g., lands on) on the material of source 290. As shown in FIG. 7, FIG. 8A, and FIG. 8B, dielectric pillars 644, 646, and 646′ can have different lengths (e.g., different heights). As shown in FIG. 7, FIG. 8A, and FIG. 8B, the length of each dielectric pillar 644 (e.g., from source 290 to an end at level 723L) can be greater than the length of each of dielectric pillars 646 and 646′. As shown in FIG. 7, the length of pillar 550 can be greater than the length of each of dielectric pillars 646 and 646′.

As shown in FIG. 7, FIG. 8A, and FIG. 8B, dielectric pillars 644 can extend through (e.g., go through) dielectric materials 531 (labeled in FIG. 7) and conductive materials 532 (labeled in FIG. 7) of decks 521, 522, and 523. The length of each dielectric pillar 644 can be measured from source 290 to an end portion (e.g., top portion) 644T of dielectric pillar 646 that is located at least at level 723L (e.g., at level 723L or above level 723L) in the Z-direction.

Dielectric pillars 646′ (FIG. 8B) can extend through (e.g., go through) dielectric materials 531 and conductive materials 532 of decks 521 and 522. The length of each dielectric pillar 646′ can be measured from source 290 to an end portion (e.g., top portion) 646′T of dielectric pillar 646′ at level 722L.

Dielectric pillars 646 (FIG. 8A) can extend through (e.g., go through) dielectric materials 531 and conductive materials 532 of deck 521. The length of each dielectric pillar 646 can be measured from source 290 to an end portion (e.g., top portion) 646T of dielectric pillar 646 at level 721L.

As shown in FIG. 8A and FIG. 8B, dielectric pillars 644, 646, and 646′ have widths W1, W3, and W2′, respectively, in the X-direction. Width W1 is greater than width W2. Width W1 is greater than width W2′. Widths W2 and W2′ can be equal to each other.

FIG. 8A shows regions 851A and 851B adjacent respective sides (e.g., left and right sides in the X-direction) of dielectric structure 451 between blocks BLK0 and BKL1. Region 815A is between (e.g., left side) dielectric structure 451 (between the left side of dielectric structure 451) and dielectric pillar 644 of block BLK0. Region 815B is between dielectric structure 451 (between the right side of dielectric structure 451) and dielectric pillar 644 of block BLK1. As shown in FIG. 8A, dielectric pillars 646 of respective blocks BLK0 and BLK1 can be located in regions 815A and 815B.

As described above, damage such as tier collapse, tier bending, or both may occur during the processes of forming memory device 200. Regions 815A and 815B may be more susceptible to such damage. Including dielectric pillars 644 at regions 815A and 815B can further improve support at regions 815A and 815B to prevent such damage. Moreover, including dielectric pillars 646 and 646′ at other regions of memory device 200 in addition to regions 851A and 851B can further improve support in memory device 200. For example, dielectric pillars 646 and 646′ can be included in regions where dielectric pillars 644 are not located or in regions outside the boundary (e.g., outside the cut) that form access for conductive contacts in portions of staircase structure of memory device 200 (e.g., staircase structure 420₀ or 420₁ in FIG. 4).

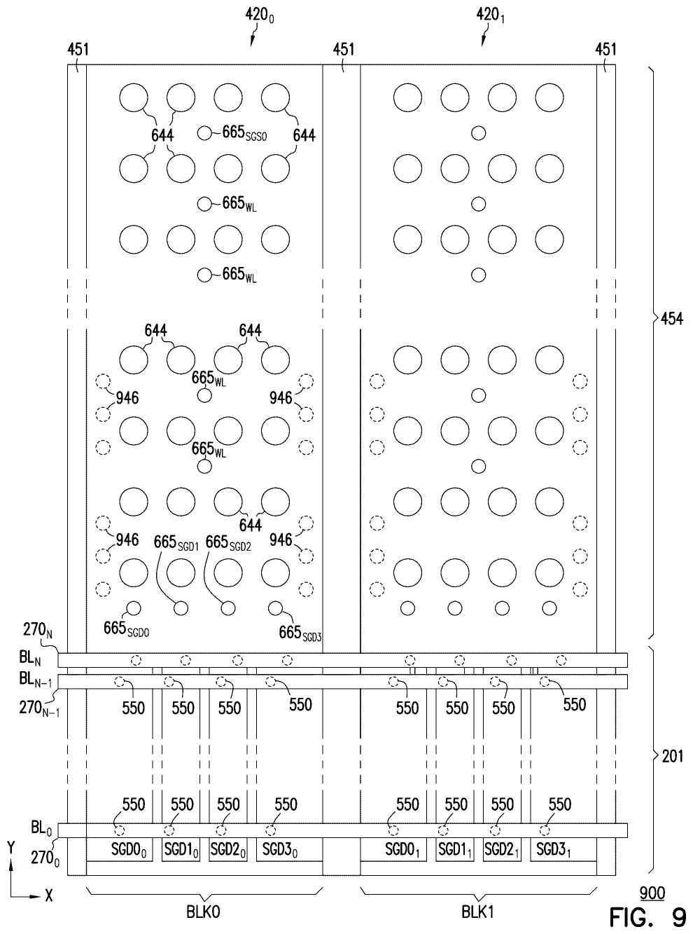

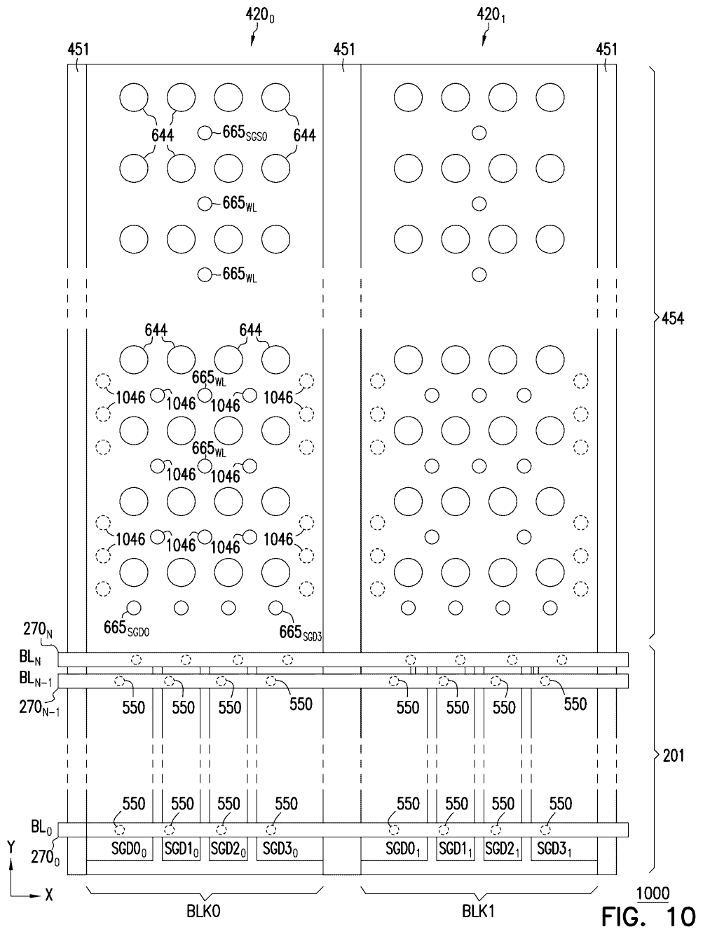

FIG. 9 shows a memory device 900 that can be variation of memory device 200, according to some embodiments described herein. As shown in FIG. 9, memory device 900 can include elements that are similar to or the same as the elements of memory device 200 of FIG. 6. For simplicity, descriptions of similar or the same elements between memory devices 200 and 900 are not repeated. In FIG. 9, dielectric pillars 946 can be any combinations dielectric pillars 646 and 646′ of FIG. 6. In comparison with memory device 200 of FIG. 6, memory device 900 of FIG. 9 can include a different pattern of dielectric pillars 946. For example, like memory device 200 of FIG. 6, memory device 900 in FIG. 9 can have a row of dielectric pillars 946 adjacent dielectric structure 451. However, the number of dielectric pillars 946 and the locations of dielectric pillars 946 in memory device 900 can be different from those of dielectric pillars 646 in memory device 200. For example, the locations of dielectric pillars 946 can be selected based on which regions of memory device 900 that are more susceptible to be damaged (e.g., collapsed or bending). Including dielectric pillars 946 in memory device 900 allows it to have improvements and benefit like those of memory device 200.

FIG. 10 shows a memory device 1000 that can be variation of memory device 200, according to some embodiments described herein. As shown in FIG. 10, memory device 1000 can include elements that are similar to or the same as the elements of memory device 200 of FIG. 6. For simplicity, descriptions of similar or the same elements between memory devices 200 and 1000 are not repeated. In FIG. 10, dielectric pillars 1046 can be any combinations dielectric pillars 646 and 646′ of FIG. 6. In comparison with memory device 200 of FIG. 6, memory device 1000 of FIG. 10 can include a different pattern of dielectric pillars 1046. For example, like memory device 200 of FIG. 6, memory device 1000 in FIG. 10 can have a row of dielectric pillars 1046 adjacent dielectric structure 451. However, the number of dielectric pillars 1046 and the locations of dielectric pillars 1046 in memory device 1000 can be different from those of dielectric pillars 646 in memory device 200. For example, the locations of dielectric pillars 1046 can be selected based on which regions of memory device 1000 that are more susceptible to be damaged (e.g., collapsed or bending). Including dielectric pillars 1046 in memory device allows it to have improvements and benefit like those of memory device 200.

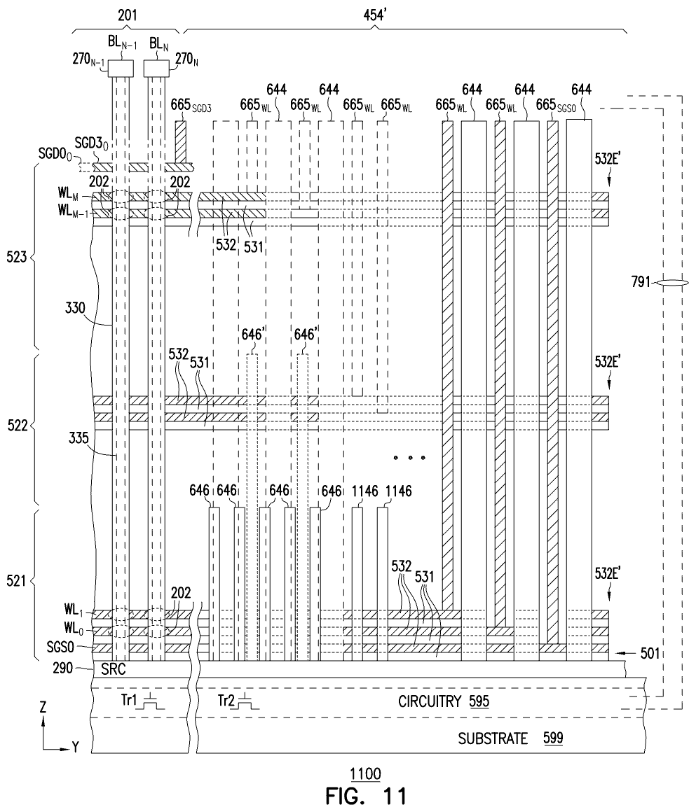

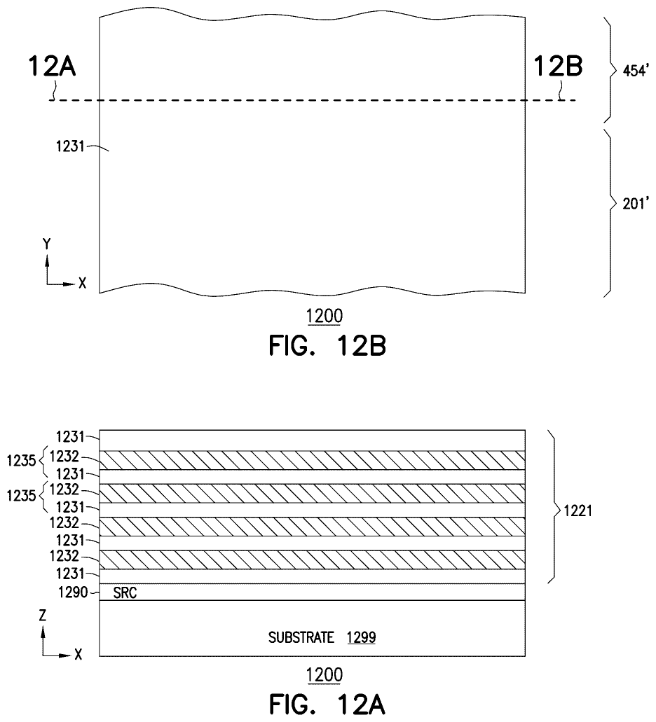

FIG. 11 shows a memory device 1100 that can be variation of memory device 200, according to some embodiments described herein. As shown in FIG. 11, memory device 1100 can include elements that are similar to or the same as memory device 200 shown in FIG. 7. Differences between memory devices 200 and 1100 include the absence of a staircase structure (e.g., staircase structure 420₀ of FIG. 7) in memory device 1100. As shown in FIG. 11, conductive materials 532 can have edges 532E′ and the same length, such that edges 532E can be aligned (e.g., vertically aligned) with each other as shown in FIG. 11. Further, as shown in FIG. 11, memory device 1100 can include pillars 1146 that can be located under (e.g., directly under) respective conductive contacts 665_{WL}. Memory device 1100 can improvements and benefit like those of memory device 200.

The above description with reference to FIG. 2 through FIG. 11 describes the structure of memory devices 200, 900, and 1100. Some or all of the structure of memory devices 200, 900, and 1100 can be formed using processes associated with the processes described below with reference to FIG. 12A through FIG. 17B.

FIG. 12A through FIG. 17B show different views of elements during processes of forming a memory device 1200, according to some embodiments described herein. FIG. 12A shows a side view (e.g., cross-section) in the X-Z direction of a portion of memory device 1200 along line 12A-12A of FIG. 12B. FIG. 12B is a top view (in the X-Y direction) of a portion of memory device 1200. In FIG. 12B, region 454′ is similar to region 454 of memory device 200 of FIG. 6. Memory array 201′ is similar to memory array 201 of memory device 200 of FIG. 6.

FIG. 12A and FIG. 12B, the processes of forming memory device 1200 can include forming a material 1290 over substrate 1299. Material 1290 can form part of a source (e.g., associated with signal SRC) that is similar to source 290 of FIG. 7. Substrate 1299 is similar to (e.g., can correspond to) substrate 599 (FIG. 7) of memory device 200.

The processes associated with FIG. 12A and FIG. 12B include forming dielectric materials (levels of dielectric materials) 1231 and dielectric materials (levels of dielectric materials) 1232 over substrate 1299 (e.g., over material 1290). Dielectric materials 1231 can include silicon dioxide. Dielectric materials 1232 can include silicon nitride. Dielectric materials 1231 and 1232 can be sequentially formed one material after another over substrate 1299 in an interleaved fashion, such that dielectric materials 1231 can be interleaved with dielectric materials 1232.

As shown in FIG. 12A, dielectric materials 1231 and 1232 can form tiers (tiers of materials) 1235. Tiers 1235 are located one over another in the Z-direction. Each tier 1235 can include a respective level of dielectric material 1231 and a respective level of dielectric material 1232. As shown in FIG. 12A, tiers 1235 can be included in a deck 1221 of memory device.

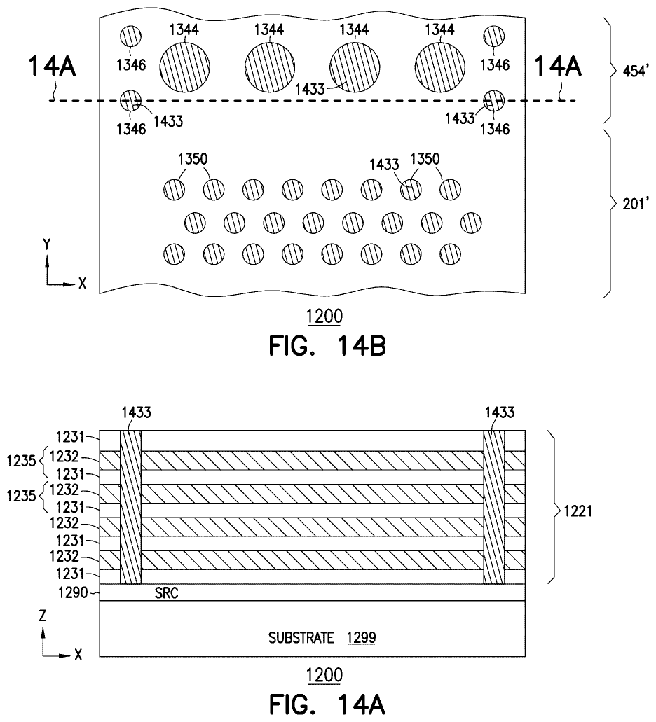

FIG. 13A and FIG. 13B show memory device 1200 after openings (e.g., holes) 1344, 1346, and 1350 are formed in respective region 454′ and region of memory array 201′. Forming openings 1344, 1346, and 1350 can include removing a portion of dielectric materials 1231 and 1232 at the locations of contact openings 1344, 1346, and 1350. In subsequent processes of forming memory device 1200, part memory cell strings of memory device 1200 can be formed at the locations of respective openings 1350. In subsequent processes of forming memory device 1200, part of dielectric pillars (like dielectric pillars 644 of FIG. 7) can be formed at locations of respective openings 1350. In subsequent processes of forming memory device 1200, part of dielectric pillars (like dielectric pillars 646 of FIG. 7) can be formed at locations of a respective openings 1346.

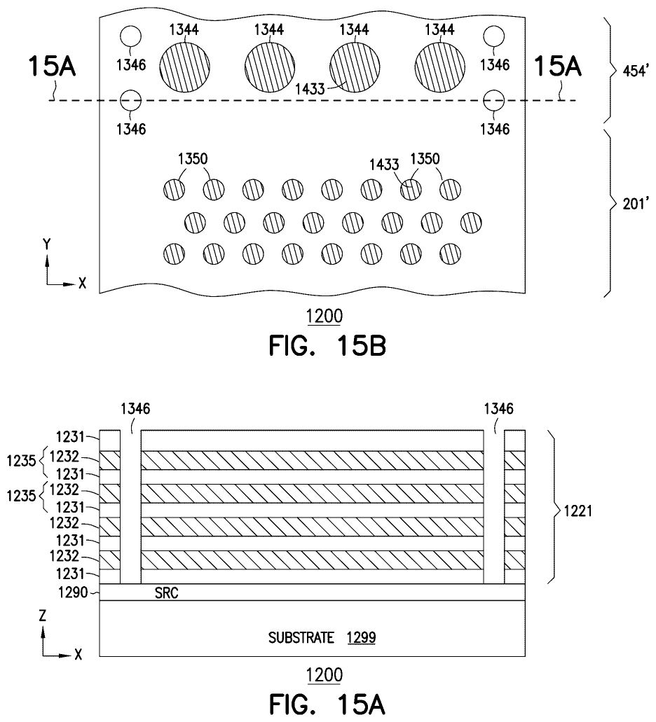

FIG. 14A and FIG. 14B show memory device 1200 after a material (or materials) 1433 is formed (e.g., filled) in openings 1344, 1346, and 1350. In subsequent processes of forming memory device 1400, material 1433 can be removed (e.g., removed at different times) from openings 1344, 1346, and 1350. Thus, material 1433 can be called a sacrificial material. An example of material 1433 can include carbon or other materials. Forming material 1433 can include forming a material (e.g., carbon) in openings 1344, 1346, and 1350. A chemical mechanical polishing (CMP) process can be performed after material 1433 is formed.

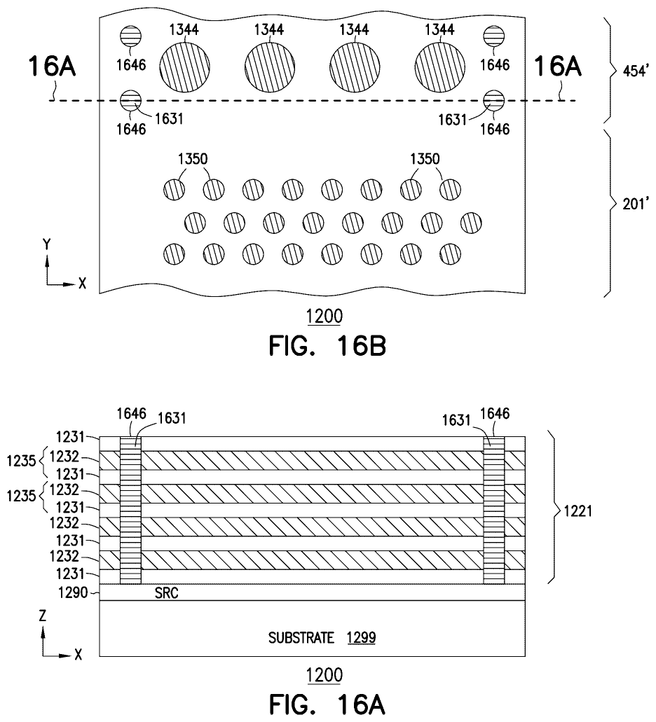

FIG. 15A and FIG. 15B show memory device 1200 after material 1433 is removed (exhumed) from openings 1346. Material 1346 can remain in openings 1344 and 1350.

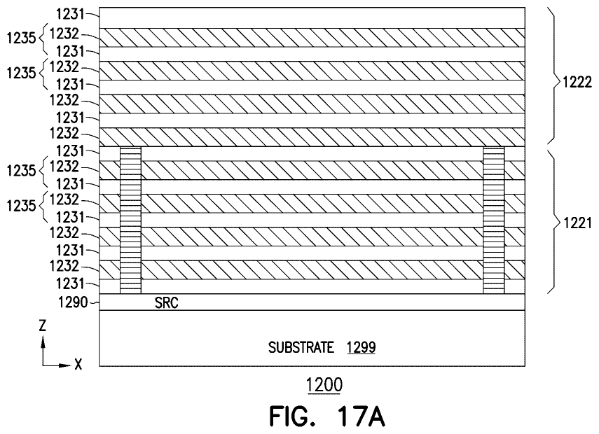

FIG. 16A and FIG. 16B show memory device 1200 after dielectric pillars 1646 are formed. Dielectric pillars 1646 are similar to dielectric pillar 646 of memory device 200 of FIG. 7, FIG. 8A, and FIG. 8B. Forming dielectric pillars 1646 can include forming (e.g., filling) a material 1631 in openings 1346 (labeled in FIG. 15A). In an example, material 1646 can include silicon dioxide.

After dielectric pillars 1646 are formed, other elements of memory device 1200 can be formed in subsequent processes of forming memory device 1200. For example, the subsequent processes can include forming dielectric pillars like dielectric pillars 646′ of FIG. 8B, forming dielectric pillars like dielectric pillars 644 of FIG. 8A and FIG. 8B, and forming memory cell pillars of memory device 1200 like memory cell pillars 550 (FIG. 7).

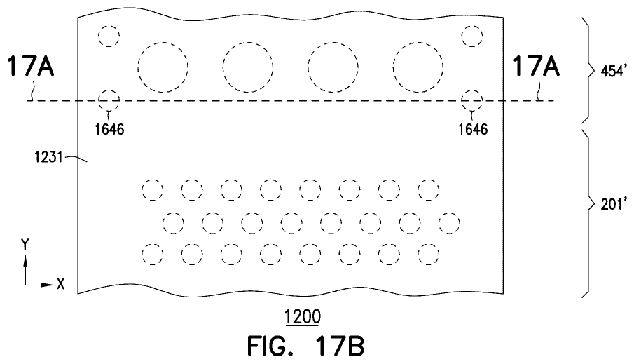

FIG. 17A and FIG. 17B show memory device 1200 after additional dielectric materials 1231 and dielectric materials 1232 are formed. As shown in FIG. 17A, additional dielectric materials 1231 and dielectric materials 1232 can be included in deck 1222 of memory device 1200. The processes described above with reference to FIG. 12A through FIG. 16B can be repeated to form additional dielectric pillars of memory device 1200, such that memory device 1200 can have dielectric pillars like the dielectric pillars of memory device 200, 900, 1000, and 1100 described above with reference to FIG. 2 through FIG. 11B.

The processes of forming memory device 1200 described above with reference to FIG. 12A through FIG. 17B can include other processes to form a complete memory device (e.g., memory device 1200). Such processes are omitted from the above description so as not to obscure the subject matter described herein. Improvements and benefits of memory device 1200 are similar to or the same as improvements and benefits of memory device 200 described above.

The illustrations of apparatuses (e.g., memory devices 100, 200, 900, 1000, 1100, and 1200) and methods (e.g., method of forming memory devices 1200 and 2600) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 900, 1000, 1100, and 1200) or a system (e.g., a computer, a cellular phone, or other electronic systems) that includes a device such as any of memory devices 100, 200, 900, 1000, 1100, and 1200.

Any of the components described above with reference to FIG. 1 through FIG. 17B can be implemented in a number of ways, including simulation via software. Thus, apparatuses, e.g., memory devices 100, 200, 900, 1000, 1100, and 1200, or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 900, 1000, 1100, and 1200 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 17B include apparatuses and methods of forming the apparatuses. One of the apparatuses includes a memory device, which includes: a first deck including first levels of conductive materials interleaved with first levels of dielectric materials; a second deck including second levels of conductive materials interleaved with second levels of dielectric materials; memory cell strings including pillars extending through at least a portion of each of the first deck and the second deck; a first conductive contact contacting a level of the first levels of conductive materials; a second conductive contact contacting a level of the second levels of conductive materials; and a dielectric pillar extending in the direction from the first deck to the second deck, the dielectric pillar including an end portion between the level of the first levels of conductive material and the level of the second levels of conductive materials. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first deck including first levels of conductive materials interleaved with first levels of dielectric materials;
a second deck including second levels of conductive materials interleaved with second levels of dielectric materials;
memory cell strings including pillars extending through at least a portion of each of the first deck and the second deck;
a first conductive contact contacting a level of the first levels of conductive materials;
a second conductive contact contacting a level of the second levels of conductive materials; and
a dielectric pillar extending in a direction from the first deck to the second deck, the dielectric pillar including an end portion between the level of the first levels of conductive materials and the level of the second levels of conductive materials.

2. The apparatus of claim 1, further comprising an additional dielectric pillar adjacent the dielectric pillar, the additional dielectric pillar includes an end portion between the level of the first levels of conductive materials and the level of the second levels of conductive materials.

3. The apparatus of claim 2, further comprising an additional dielectric pillar, the additional dielectric pillar extending through the first levels of conductive materials, the first levels of dielectric materials, the second levels of conductive materials, and the second levels of dielectric materials.

4. The apparatus of claim 3, wherein the additional dielectric pillar includes a first width, the dielectric pillar includes a second width, and the first width is greater than the second width.

5. The apparatus of claim 3, further comprising a second additional dielectric pillar, wherein the additional dielectric pillar is a first additional dielectric pillar, and wherein the dielectric pillar, the first additional dielectric pillar, and the second additional dielectric pillar include different lengths.

6. The apparatus of claim 5, wherein the first additional dielectric pillar includes a first width, the second additional dielectric pillar includes a second width, the dielectric pillar includes a third width, and wherein the first width is greater than each of the second width and the third width.

7. The apparatus of claim 1, wherein a portion of the first levels of conductive materials and a portion of the second levels of conductive material are part of a staircase structure.

8. The apparatus of claim 1, wherein:
the level of the first levels of conductive materials includes a first edge;
the level of the second levels of conductive materials includes a second edge;
the first conductive contact is between a pillar of the pillars and each of the first edge and the second edge; and
the second conductive contact is between the pillar of the pillars and each of the first edge and the second edge.

9. An apparatus comprising:
first memory cells and first control gates associated with the memory cells;
second memory cells and second control gates associated with the second memory cells;
a dielectric structure separating the first control gates from the second control gates;
a first dielectric pillar adjacent a first side of the dielectric structure, the first dielectric structure including a first length;
a second dielectric pillar located on the first side of the dielectric structure and adjacent the first dielectric pillar, the second dielectric pillar including a second length, the second length being greater than the first length;
a third dielectric pillar adjacent a second side of the dielectric structure, the third dielectric structure including a third length; and
a fourth dielectric pillar located on the second side of the dielectric structure and adjacent the third dielectric pillar, the fourth dielectric pillar including a fourth length, the fourth length being greater than the third length.

10. The apparatus of claim 9, further comprising:
a first conductive contact extending in a direction from the first control gates to the second control gates and contacting one of the first control gates; and
a second conductive contact extending in the direction from the first control gates to the second control gates, wherein the first conductive contact and the second conductive contact have different lengths.

11. The apparatus of claim 10, wherein the dielectric pillar is located under the second conductive contact.

12. The apparatus of claim 9, wherein the first dielectric pillar and the second dielectric pillar include different widths, and the third dielectric pillar and the fourth dielectric pillar include different widths.

13. The apparatus of claim 9, wherein the first memory cells and first control gates are included in a first memory cell block, and the second memory cells and the second control gates are included in a second memory cell block.

14. The apparatus of claim 9, further comprising a fifth dielectric pillar located on the first side of the dielectric structure, the fifth dielectric pillar including a length greater than the first length and less than the second length.

15. The apparatus of claim 9, further comprising a row of dielectric pillars adjacent the first side of the dielectric structure, wherein the first dielectric pillar is included in the row of dielectric pillars.

16. The apparatus of claim 15, further comprising an additional row of dielectric pillars adjacent the second side of the dielectric structure, wherein the third dielectric pillar is included in the additional row of dielectric pillars.

17. The apparatus of claim 9, wherein one of first memory cells and one of the second memory cells are associated with a memory pillar, wherein the memory cell pillar includes a length greater than each of the first length and the third length.

18. A method comprising:
forming a first dielectric pillar in a first deck of a memory device and adjacent a region between a first block of the memory device and a second block of the memory device and adjacent the first dielectric pillar; and
forming a second dielectric pillar through the first deck and a second deck of the memory device, the second deck located over the first deck, the second dielectric pillar including a first width greater than a width of the first dielectric pillar.

19. The method of claim 18, wherein forming the first dielectric pillar includes:
forming levels of first materials interleaved with levels of second materials;
forming an opening in the levels of first materials and levels of second materials; and
forming a dielectric material in the opening.

20. The method of claim 19, wherein forming the second dielectric pillar includes:
forming levels of additional first materials interleaved with levels of additional second materials over the first deck; and
forming the second dielectric pillar through the levels of first materials, the levels of second materials, the level of additional first materials, and the levels of additional second materials.
